(19) United States
(12) Patent Application Publication
(10) Pub. No.: US 2025/0076426 A1
(43) Pub. Date: Mar. 6, 2025

(54) Flexible Radiofrequency (RF) Coil for Small Field-of-View Magnetic Resonance Imaging (MRI)

(71) Applicant: The Regents of the University of California, Oakland, CA (US)

(72) Inventors: Marvin Bergsneider, Oakland, CA (US); Robert N. Candler, Oakland, CA (US); Kyunghyun Sung, Los Angeles, CA (US); Siyuan Liu, Oakland, CA (US); Jiahao Lin, Los Angeles, CA (US)

(21) Appl. No.: 18/727,067

(22) PCT Filed: Jan. 6, 2023
(86) PCT No.: PCT/US2023/060246

§ 371 Date: Jul. 5, 2024

Related U.S. Application Data
(60) Provisional application No. 63/296,958, filed on Jan. 6, 2022.

(51) Int. Cl. G01R 33/36; G01R 33/34

(52) U.S. Cl. CPC G01R 33/3628; G01R 33/34

(57) ABSTRACT

An RF coil apparatus for magnetic resonance imaging (MRI) includes a flexible RF coil configured to be positioned in a cavity of a subject proximate to a region of interest located internally in the subject and a circuit assembly coupled to the flexible RF coil and configured to be positioned external to the subject. The circuit assembly can include adjustable tune and match components. The RF coil apparatus can further include a first connector connected between the flexible RF coil and the circuit assembly and a second connector coupled to the circuit assembly and configured to connect to an MRI system.

### CROSS-REFERENCE TO RELATED APPLICATIONS

This application is based on, claims priority to, and incorporates herein by reference in its entirety U.S. Ser. No. 63/296,958 filed Jan. 6, 2022 and entitled “Flexible Radiofrequency (RF) Coil For Small Field-Of-View Magnetic Resonance Imaging (MRI).”

### BACKGROUND

There is a strong clinical need to improve the resolution of magnetic resonance imaging (MRI) for the detection of small pathological lesions. A salient example is Cushing's disease (CD): a potentially fatal disorder caused by an adrenocorticotropin hormone (ACTH)-producing pituitary tumor. Clinical magnetic resonance imaging (MRI) of the pituitary gland sometimes fails to detect small pituitary tumors due to limited signal-to-noise ratio (SNR) and spatial resolution. While the median size of pituitary tumors (microadenomas) causing CD is 5 mm, a significant percentage are less than 3 mm in size. Currently, MRI is unable to detect up to 50% of microadenomas in CD. This failure of diagnostic imaging thwarts the primary and optimal treatment of CD: surgical excision of the offending tumor. In such cases without an imaging-identifiable tumor, neurosurgeons may need to resort to surgical exploration and systemic slicing of the pituitary gland to identify the small pituitary tumors. For example, neurosurgeons must consider surgically “exploring” the anterior pituitary gland by making multiple parallel incisions typically spaced 2-3 mm apart with the hope of fortuitously encountering the tumor. In addition to the real possibility of not finding a tumor, this technique adds the risk of permanently damaging the normal gland.

Standard pituitary MRI protocols generate multi-slice 2-dimensional (2D) images with a typical in-plane resolution of 0.7×0.7 mm² and through-plane slice thickness of 3 mm. When considering various shapes of the pituitary gland, partial volume averaging, and motion-related degradation, it is not surprising that MR images with an in-plane pixel size of 0.7 mm commonly fail to detect lesions smaller than 3 mm.

One of the common factors limiting MRI spatial resolution is signal-to-noise ratio (SNR). Two approaches for increased SNR are to use higher strengths (e.g., 7T MRI scanner) and to design application-specific radiofrequency (RF) coil arrays. These two are generally additive when combined with each other. Advancements have been made with flexible RF coil arrays. Conforming the coil elements to the patient's surface anatomy achieves higher SNR in directly adjacent regions, which unfortunately is of limited value for certain regions of the anatomy located inside a subject, for example, imaging of the pituitary given that the pituitary gland is located centrally within the cranium. Another approach to improve SNR is to place a separate receive-only RF coil in close proximity to the imaging target. One example in clinical use, the endorectal coil designed for prostate imaging, has had limited use due to patient discomfort related to the relatively large diameter of the endorectal component. One prior study adopted the endorectal prostate coil for pituitary imaging. The study demonstrated a potential 10-fold increase in SNR by positioning the coil apparatus withing the sphenoid sinus via a sublabial approach in a cadaver. However, the design included a potential concern that the coil is needed to be positioned blindly, given the complete obstruction of the surgical corridor by the probe.

### SUMMARY

In accordance with an embodiment, an RF coil apparatus for magnetic resonance imaging (MRI) includes a flexible RF coil configured to be positioned in a cavity of a subject proximate to a region of interest located internally in the subject and a circuit assembly coupled to the flexible RF coil and configured to be positioned external to the subject. The circuitry assembly can include adjustable tune and match components. The RF coil apparatus can further include a first connector connected between the flexible RF coil and the circuit assembly and a second connector coupled to the circuit assembly and configured to connect to an MRI system.

In accordance with another embodiment, a magnetic resonance imaging (MRI) system includes a magnet system configured to generate a polarizing magnetic field about at least a portion of a subject, a magnetic gradient system including a plurality of magnetic gradient coils configured to apply at least one magnetic gradient field to the polarizing magnetic field; and a radio frequency (RF) system configured to apply an RF field to the subject and to receive magnetic resonance signals from the subject. The RF system can include an RF coil apparatus. The RF coil apparatus includes a flexible RF coil configured to be positioned in a cavity of a subject proximate to a region of interest located internally in the subject and a circuit assembly coupled to the flexible RF coil and configured to be positioned external to the subject. The circuit assembly can include adjustable tune and match components. The RF coil apparatus can further include a first connector connected between the flexible RF coil and the circuit assembly and a second connector coupled to the circuit assembly and the RF system.

### BRIEF DESCRIPTION OF THE DRAWINGS

The present invention will hereafter be described with reference to the accompanying drawings, wherein like reference numerals denote like elements.

FIG. 1 is a perspective view of a radiofrequency (RF) coil apparatus including a flexible RF coil in accordance with an embodiment;

FIG. 2 illustrates an example application of the RF coil apparatus including a flexible RF coil as shown in FIG. 1 in accordance with an embodiment;

FIG. 3A is a schematic diagram of the RF coil of the RF coil apparatus shown in FIG. 2 where the RF coil plane is parallel to an imaging plane in accordance with an embodiment;

FIG. 3B is a schematic diagram of an RF coil of the RF coil apparatus shown in FIG. 2 where the RF coil is rotated at an angle theta (θ) in accordance with an embodiment;

FIG. 4 illustrates a comparison of a measured and simulated reflection coefficient, S11, of the flexible RF coil of the RF coil apparatus of FIG. 2 with and without a load in accordance with an embodiment;

FIG. 5 illustrates example signal SNR maps and simulated effective transverse Bi field distributions at θ=0°, 38°, 70°, and 90° in accordance with an embodiment;

FIG. 6 illustrates a comparison of example high-resolution magnetic resonance (MR) images acquired using a commercial head coil and the flexible RF coil of the RF coil apparatus of FIG. 2 in accordance with an embodiment;

FIG. 7 is a graph illustrating mean SNR at various region of interest depths and rotation angles in accordance with an embodiment;

FIG. 8 shows a Bland-Altman plot for SNR of two repeated MR scans in accordance with an embodiment; and

FIG. 9 is a schematic diagram of an example magnetic resonance imaging (MRI) system in accordance with an embodiment.

### DETAILED DESCRIPTION

The present disclosure describes a radiofrequency (RF) coil apparatus that includes a flexible RF coil having dimensions configured to provide a small field-of-view and to allow positioning of the flexible RF coil inside a cavity of a subject (e.g., a patient) and in close proximity to a region of interest internal to the subject, enabling high signal-to-noise-ratio (SNR) MRI of the region of interest. The increased SNR provided from the RF coil apparatus can enable markedly higher resolution imaging compared to conventional external RF coils. The RF coil apparatus can advantageously enable a much increased spatial resolution than that currently provided with standard MR imaging. In some embodiments, the increased SNR can enable control over the measurement time (e.g., faster acquisitions of images or snapshots). The RF coil apparatus may also include a circuit assembly (or box) coupled to the flexible RF coil and configured to be located external to the subject, and a connector configured to couple the circuit assembly to an MRI system. In some embodiments, the flexible RF coil can be a miniature single-loop flexible coil. In some embodiments, the miniature flexible RF coil can be, for example, a butterfly coil, a figure-of-eight coil, or an array of coils. In some embodiments where the miniature flexible RF coil is an array of coils, the array of coils can be configured to look outward from the cavity (e.g., a sphenoid sinus cavity) in which the RF coil is positioned. The flexible RF coil may be coupled to the circuit assembly using a connector such as, for example, a coaxial cable. The flexible RF coil and a portion of the RF coil connector can form an intracavity portion of the RF apparatus that can be inserted into the cavity of the subject.

The circuit assembly can include adjustable tune and match components configured to allow fine tuning of the RF coil. Advantageously, the circuit assembly can be located outside of the subject when the RF coil is inserted into a cavity of the subject. Locating the circuit assembly external to the subject can enable the dimensions of the RF coil to be minimized to fit inside the body of the subject. In some embodiments, the circuit assembly can also include a pre-amplifier. In some embodiments, the region of interest can be the pituitary gland and the flexible RF coil of the RF coil apparatus is configured with dimensions to allow insertion of the flexible RF coil through a nostril of the subject (i.e., endonasally) and into the sphenoid sinus cavity where the flexible RF coil can be positioned near the pituitary gland. For example, the single-coil flexible RF coil can be configured to be positioned millimeters from or placed against the pituitary gland. In some embodiments, the flexible RF coil of the RF coil apparatus can be designed with different diameters, geometries, resonance frequencies, and placement configurations. In some embodiments, different flexible RF coils with different sizes and shapes can be provided for an RF coil apparatus such that an RF coil with an optimal shape and dimensions may be selected based on the specific anatomy of each patient.

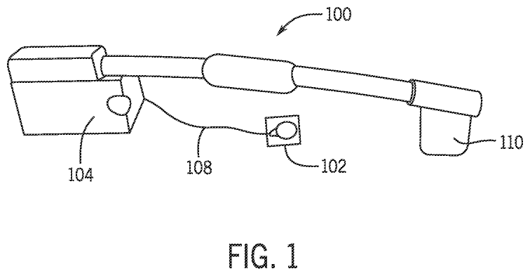

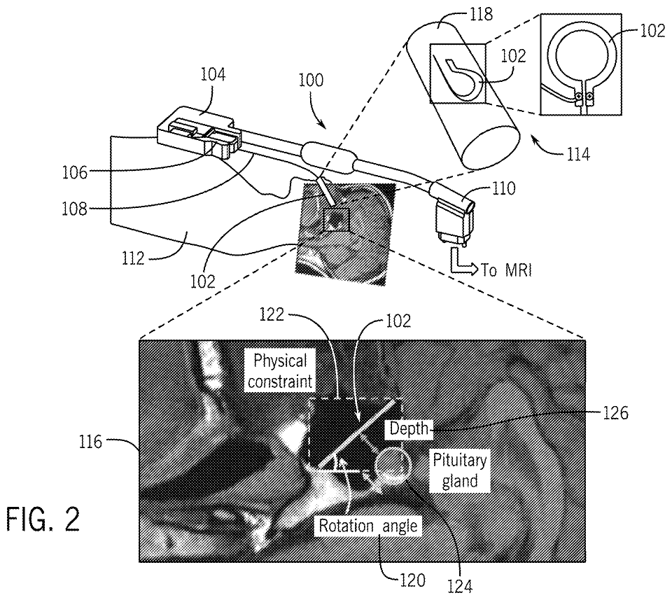

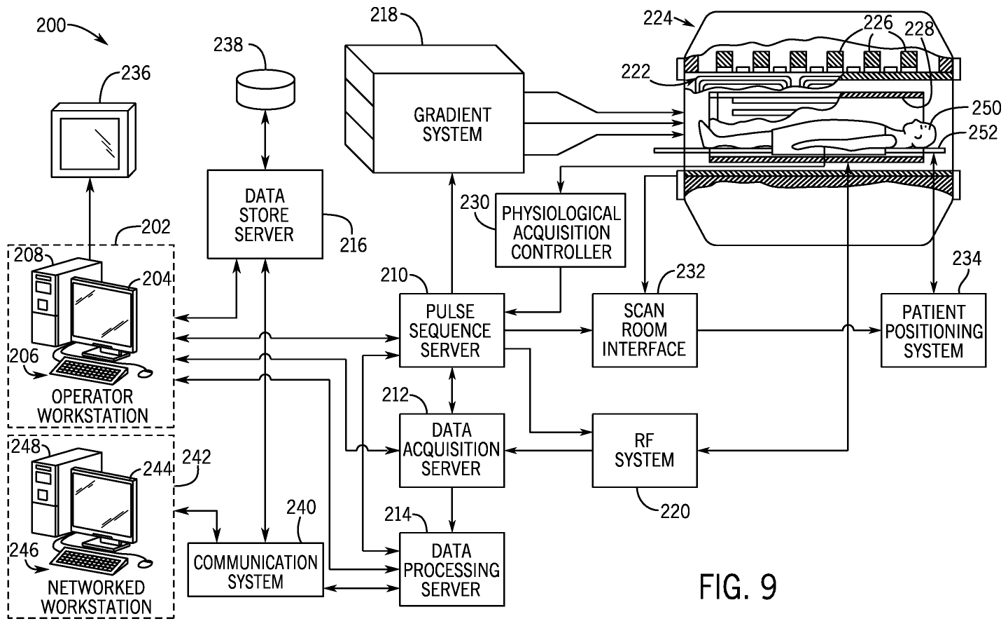

FIG. 1 is a perspective view of a radiofrequency (RF) coil apparatus including a flexible RF coil in accordance with an embodiment. RF coil apparatus 100 can include a flexible RF coil 102, a circuit assembly 104, a first connector 108, and a second connector (or docking port) 110. In some embodiments, the flexible RF coil 102 can have a set of dimensions (e.g., a diameter and thickness) configured to provide a small field-of-view and to allow positioning of the flexible RF coil 102 inside a cavity of a subject (e.g., a patient) and in close proximity to a region of interest internal to the subject. Positioning the flexible RF coil 102 in close proximity to the region of interest internal to the subject can enable high SNR which can allow for higher resolution imaging and can provide faster acquisition times. In some embodiments, the flexible RF coil 102 can be, for example, a single-loop flexible coil as shown in FIGS. 1 and 2, a butterfly coil, a figure-of-eight coil, or an array of coils (e.g., an array of coils configured to look outward from the cavity in which the flexible RF coil is positioned). In some embodiments, the flexible RF coil 102 can consist of a loop made from a single continuous trace (e.g., copper) on a flexible printed circuit board (PCB). From a coil design perspective, in some embodiments, the coil diameter should not only be large enough to provide sufficient coverage for the region of interest but should also fit within the physical spatial constraints of the cavity of the subject. Specifically, the diameter of the RF coil 102 can be configured to be large enough (e.g., larger than the region of interest) such that the region of interest is in the region of high sensitivity of the RF coil 102. The diameter of the RF coil 102 can also be configured to be large enough to achieve sensitivity at the depth of the farthest point of the region of interest because the optimal coil diameter is proportional to the imaging depth of interest, which may be given by:

$${R}_{optimal} = \frac{{d}_{max}}{\sqrt{5}} \qquad Eqn . 1$$

where dₘₐₓ is the maximum distance of interest from the RF coil 102. Placement of the RF coil 102 inside a cavity of a subject and in close proximity to a region of interest internal to the subject can require that the RF coil 102 be flexible to be able to bend slightly as needed. In some embodiments, the flexible RF coil 102 may be configured to be placed in close proximity to the region of interest or placed against the region of interest. In some embodiments, the orientation of the RF coil 102 when placed in the cavity and in close proximity to the region of interest can be parallel to the orientation of the main magnetic field, B₀, generated by an MRI system (e.g., MRI system 200 shown in FIG. 9). RF coil 102 of the RF coil apparatus 100 can be designed with different diameters, geometries, resonant frequencies, and placement configurations based on, for example, the MR imaging application, the anatomy (or region of interest) of the subject to be imaged, the cavity of the subject in which the RF coil 102 will be placed, and the physical spatial constraints of the cavity for the specific subject being imaged. The cavity configuration and size can vary between different subjects. In some embodiments, different flexible RF coils 102 with different sizes and shapes can be provided for an RF coil apparatus 100 such that an RF coil 102 with an optimal shape and dimensions may be selected based on the specific anatomy (e.g., the specific physical spatial constraints of the anatomy) of each patient.

The flexible RF coil 102 may be coupled to a circuit assembly 104. In some embodiments, the flexible RF coil 102 may be coupled and connected to the circuit assembly 104 using a first connector 108 (e.g., a cable). In some embodiments, the first connector 108 may be a coaxial cable. The circuit assembly 104 can be advantageously configured to be located remotely and external to the subject when the RF coil 102 is inserted into a cavity of the subject. Locating the circuit assembly 104 external to the subject can enable the dimensions of the RF coil 102 to be minimized to fit inside the body of the subject. The circuit assembly 104 can include a housing and circuit elements or components. In some embodiments, the circuit assembly 104 can include adjustable tune and match components 106 (shown in FIG. 2) configured to allow fine tuning of the RF coil 102. In some embodiments, the circuit assembly 104 can also include a pre-amplifier. The circuit assembly 104 can also be configured to actively decouple the loop of the RF coil 102 during a transmit portion of a pulse sequence performed by an MRI system (e.g., MRI system 200 shown in FIG. 9 and discussed further below). In some embodiments, the circuit assembly 104 can be a three-dimensional (3D) printed circuit box. The first connector 108 can have a length to allow the circuit assembly 104 to be positioned outside of the body of the subject when the RF coil 102 is positioned in a cavity of the subject and to allow the tune and match components to have the same tune and match effects as if the tune and match components were placed on the RF coil 102. In some embodiments, the first connector 108 and circuit assembly 104 are configured so that the tune an match components are placed at multiples of a half wavelength away from the RF coil 102 which can result in the tune and match components having the same tune and match effects as if the tube and match components are placed in the RF coil 102. The remote circuit assembly 104 (including the remote tune and match components) allows for only the RF coil 102 and a portion of the first connector 108 to be required to be positioned inside the subject. Accordingly, the flexible RF coil 102 and a portion of the first connector 108 coupling the RF coil 102 and the circuit assembly 104 can form an intracavity portion of the RF coil apparatus 100. In some embodiments, the intracavity portion (e.g., the flexible RF coil and cable) may be sterilized using known methods. In some embodiments, the flexible RF coil 102 can be coated with known materials (e.g., biocompatible materials) to be waterproofed and heat insulated to prevent thermal burn. In some embodiments, the RF coil apparatus 100 can also include a second connector 110 to couple the RF coil apparatus 100 (e.g., the circuit assembly 102) to an MRI system (e.g., RF system 220 of MRI system 200 shown in FIG. 9). In some embodiments, the tune and match components 106 can be used to tune the RF coil 102 in real time to the appropriate resonance frequency. Accordingly, the RF coil apparatus 100 can be suitable for any field strength MRI system.

As mentioned above, the RF coil apparatus 100 can be configured to allow positioning of the flexible RF coil 102 inside a cavity of a subject (e.g., a patient) and in close proximity to a region of interest internal to the subject. FIG. 2 illustrates an example application of the RF coil apparatus including a flexible RF coil as shown in FIG. 1 in accordance with an embodiment. In some embodiments, the Rf coil apparatus 100 can be configured for use for MR imaging of the pituitary gland. While the following description of FIGS. 2-8 is discussed in terms of an example RF coil apparatus for imaging of the pituitary gland, it should be understood that the RF coil apparatus may be configured for the imaging of other anatomy (or regions of interest) located internal to a subject (or patient).

In FIG. 2, the region of interest (or target region or organ) is the pituitary gland 124. The RF coil apparatus 100 can includes a single loop flexible RF coil 102 that can be configured with dimensions (e.g., length and thickness) to allow insertion of the flexible RF coil 102 through a nostril of the subject 112. As illustrated in FIG. 2, in some embodiments, the flexible RF coil 102 can be easily placed via one nostril of a subject 112 (i.e., endonasally) and optimally situated within the sphenoid sinus cavity, for example, under direct endoscopic visualization. In some embodiments, the ideal orientation of the flexible RF coil 102 can be parallel to the orientation of the main magnetic field, B₀. FIG. 2 includes an enlarged representation 114 of the RF coil 102 including a cylinder 118 that represents a region of sensitivity of the RF coil 102 for imaging. As mentioned above, in some embodiments the single-loop flexible RF coil 102 can consist of a loop made from a single continuous trace (e.g., copper) on a flexible printed circuit board (PCB). For example, for pituitary imaging, the single loop flexible RF coil 102 can consist of a 20 mm diameter loop made from a single continuous copper trace (3 mm in width and 17.8 μm in thickness) on a flexible PCB. In some embodiments the RF coil 102 diameter should not only be large enough to provide sufficient coverage for pituitary MRI but should also fit within the physical spatial constraint of the sphenoid sinus cavity. Specifically, the diameter of the RF coil 102 can be configured to be large enough (e.g., larger than the pituitary) that the pituitary is in the region of high sensitivity (e.g., illustrated by cylinder 118) of the RF coil 102. As mentioned above, the diameter of the RF coil 102 can also be configured to be large enough to achieve sensitivity at the depth of the farthest point of the pituitary because the optimal coil diameter is proportional to the imaging depth of interest (e.g., as given by Eqn. 1 above).

Endonasal placement of the RF coil 102 can require that the RF coil 102 be flexible and configured to be able to bend slightly beyond a U-shape in order to pass by the nostril. In some embodiments, an RF coil diameter up to 2.5-cm could be inserted in a nostril without hyperangulation (kinking). Once past the nostril, further advancement of the flexible RF coil 102 into the sphenoid sinus cavity can be easy and safe. FIG. 2 includes an enlarged view of the placement of the RF coil 102 in a sphenoid sinus cavity with a depth of interest 126 to the pituitary gland 124. The flexible RF coil 102 can be placed in close proximity to or placed against the pituitary gland 124. For example, the flexible RF coil 102 can be configured to be positioned millimeters from or placed against the pituitary gland 124. As shown in the enlarged region 116 of FIG. 2, an RF coil rotation angle 120 can defined as the angle between the RF coil 102 plane and an MRI system scanner bed (e.g., scanner or patient bed 252 shown in FIG. 9).

A circuit assembly 104 of the RF coil apparatus can be configured to be located outside the body of the subject 112. A first connector 108 (e.g., a cable) of the RF coil apparatus 100 can be used to connect and couple the flexible RF coil 102 to the circuit assembly 104. For example, a coaxial cable (e.g., 50 Ω, 1 mm diameter, 20 cm in length) can be used to connect (or couples) the RF coil 102 to the circuitry assembly 104. In some embodiments, the circuit assembly 104 can include a housing and adjustable tune and match components 106. In some embodiments, the circuit assembly can also include a preamplifier (not shown). In some embodiments, the circuit assembly 104 can be a 3D printed circuit box. The first connector 108 can have a length that allows the circuit assembly 104 to be outside of and external to the subject 112 when the RF coil 102 is inserted into the sphenoid sinus cavity near the pituitary gland. In some embodiments, the first connector 108 is configured to enable the circuit assembly 104 (and tune and match components 106) to be positioned at multiples of a half wavelength away from the RF coil 102 so that the tune and match components 106 can have the same tune and match effects as if they were placed on the RF coil 102. For the example of pituitary MRI imaging as shown in FIG. 2, the RF coil apparatus 100 can be tuned to a resonance frequency of 123.2 MHz (for 3T imaging) and impedance matched by adjusting the electrical components contained in the circuit assembly 104. In some embodiments, the circuit assembly 104 can also be designed to actively decouple the loop of the RF coil 102 during the transmit portion of a pulse sequence performed by an MRI system (e.g., MRI system 200 shown in FIG. 9 and described further below). As discussed above, circuit assembly 104 including the remote tune and match components 106 positioned outside the subject 112 and remote from the RF coil 102 allow for only the RF coil 102 and a portion of the first connector 108 to be required to be inserted endonasally. The flexible RF coil 102 and the portion of the first connector 108 coupling the RF coil 102 and the circuit assembly 104 can form an intracavity portion of the RF coil apparatus 100. In some embodiments, the RF coil apparatus 100 can also include a second connector (or docking port) 110 to couple the RF coil apparatus 100 to an MRI system (e.g., RF system 220 of MRI system 200 shown in FIG. 9).

In some embodiments, the RF coil apparatus 100 configured for MR imaging of the pituitary gland can be used in a clinical implementation where the RF coil apparatus 100 may be used as part of the initial portion of an endoscopic endonasal operation, including the sphenoidotomy, drilling (removal) of intrasphenoidal septa, and other sphenoid bone if necessary (so called “conche” sella). In this example application, the anterior sellar bone can remain to protect the sellar contents per se. A saline soaked collagen sponge can be placed over the clival recess and reduce air-bone artifacts. The sterile RF coil (e.g., flexible RF coil 102) can then be placed through a single nostril of the subject and then positioned as much as possible parallel to the ground floor or scanner bed (which are both parallel to the B₀ field). An intrasphnoid balloon can then be inflated to secure the RF coil 102 against the sellar face. The patient (or subject) can then undergo an intra-operative MRI scan with, for example, the immediate interpretation of the images to be able to identify a previously unidentifiable lesion.

The following example sets forth, in detail, ways in which the RF coil apparatus of the present disclosure was evaluated and ways in which the RF coil apparatus of the present disclosure may be used or implemented, and will enable one of ordinary skill in the art to more readily understand the principles thereof. The following example is presented by way of illustration and are not meant to be limiting in any way.

In this example study, the spatial distribution of the image SNR of the flexible RF coil (e.g., the RF coil 102 shown in FIG. 2), was investigated via both numerical simulation and phantom experiments. The feasibility of increased SNR within the pituitary gland was also explored based on simulated surgical placements. Compared to a commercial head coil, the evaluated RF coil 102 for imaging of the pituitary gland achieved up to a 19-fold SNR improvement within the region of interest, and the simulation and phantom experiment reached a good agreement, with an error of 1.1%±0.8%. High resolution MRI scans further demonstrated the visual improvement of the disclosed flexible RF coil 102 against the commercial head coil. Cross-validation of the simulation and the phantom experiment showed the potential of using the numerical simulation model to accelerate the coil deign prototyping and iteration and to optimize RF coil design including the potential to select an optimal RF coil from a predetermined range of coil shapes and sizes.

In this example study, the disclosed RF coil design was evaluated using a custom-built phantom which allowed the precise measurement of SNR. The ideal orientation of the RF coil 102 inside the subject may be parallel to the orientation of the main magnetic field, B₀. As the surgical positioning for endoscopic surgery is supine, however, with the sphenoid sinus anatomy this RF coil orientation may not be anatomically possible in some cases. Therefore, in this example study, the phantom was designed to allow the study of the effect of coil angulation relative to the B₀ field. Two aims of this example study were to 1) investigate spatial distribution of the image SNR for various coil rotation angles (θ) using a numerical simulation model and phantom experiments, and 2) test the feasibility of increased SNR within the pituitary gland based on simulated surgical placement results.

Modeling of MRI RF coils can be an important step in coil design and development. In this example study, a 3D coil model was developed in simulation software to study the magnetic field distribution of the RF coil 102. In this example study for pituitary imaging, a circular loop RF coil with a 20 mm inner diameter and a trace width of 3 mm was set up in the frequency domain. The RF coil was assigned as Perfect Electric Conductor surface and the current flowing in the coil was set to 1 A. The sample properties in the simulation were set up according to the material properties of the agar-carrageenan gel used in the phantom. For this finite element simulation, a maximum element size of 0.5 mm was used on the ROI, and the simulated fields from the RF coil, Bi fields, at each vertex were for post-processed using known post-processing software.

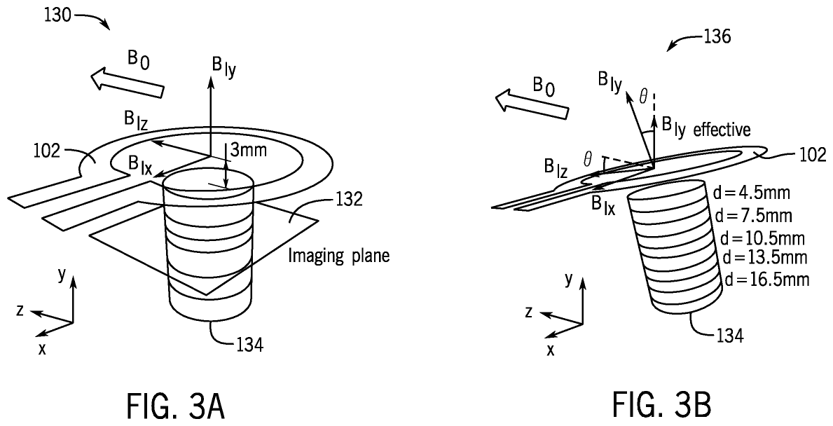

In this example study, the simulated amplitude of the effective transverse field B_{1xyeffective} at the resonance frequency within the ROI was evaluated and then compared with the MRI scan results. The magnetic field components can be simulated with the RF coil plane parallel to the B₀ field (θ=0°) as shown by diagram 130 in FIG. 3A, and then the amplitude of the effective transverse field at a certain rotation angles θ (0°<θ≤90°) with respect to B₀, as shown in diagram 136 in FIG. 3B, can be derived as:

$${B}_{1 yeffective} = {B}_{1 y} \cdot cos θ - {B}_{1 z} \cdot sin θ \qquad Eqn . 2$$

$${B}_{1 xyeffectivd} = \sqrt{{B}_{1 x} {B}_{1 x}^{*} + {B}_{1 yeffective} {B}_{1 yeffective}^{*}} \qquad Eqn . 3$$

where B₁ₓ, B_{1y}, and B_{1z} are the magnetic field components for the RF coil 102 (e.g., an Rf receiving coil) in x, y, z directions at θ=0°. In this example, B₁ₓ, B_{1y}, and B_{1z} remain constant during the rotation.

FIG. 3A is a schematic diagram of the RF coil of the RF coil apparatus shown in FIG. 2 where the RF coil plane is parallel to an imaging plane in accordance with an embodiment and FIG. 3B is a schematic diagram of an RF coil of the RF coil apparatus shown in FIG. 2 where the RF coil is rotated at an angle theta (θ) in accordance with an embodiment. In FIGS. 3A and 3B. cylinder 134 represents the region of interest (ROI) at various distances d from the RF coil 102. B₀ is in the +z axis. In FIG. 3A, the RF coil 102 resides in the x-z plane at θ=0° and is parallel to an imaging plane 132. In FIG. 3B, the RF coil 102 is rotated around the x-axis at an angle, θ, where: 0°<θ≤90°.

An experimental setup was designed for evaluation of the RF coil apparatus 100. In this example study, a 3D-printed phantom was designed and manufactured to include a cavity to roughly mimic the sphenoid sinus dimensions. A surrounding cylindrical jar allowed for easy rotation of the assembly effectively tilting the RF coil rotation angle relative to the B₀ field. In this example study, the cavity of the phantom holds the RF coil and a resolution plate was placed directly on the outside of the cavity of the phantom to measure the SNR at the location where the pituitary gland for a subject would be. To assess imaging resolution, five holes, ranging from 1 mm to 2.8 mm in diameter (e.g., 1 mm, 1.6 mm, 2 mm, 2.4 mm, and 2.8 mm), were drilled into the resolution plate, for example, an acrylic plate (2.5 cm thick and 7.5 cm wide), which was attached under the cavity of the phantom. These five smaller holes can be used for visual demonstration. In addition, a center hole of 12.7 mm in diameter was drilled to provide sufficient volume for SNR measurements. The cavity of the phantom and the resolution plate were then fixed inside a transparent cylindrical plastic jar, parallel to the jar wall. In this example study, the plastic jar was chosen to have a similar size as a human head, 13 cm in diameter and 12 cm in height. The plastic jar was rested on a pair of 3D-printed supporters, so the jar was able to be rotated and set at the desired RF coil (and scan) angle. In this example study, outside of the cavity can surrounded by agar gel. The plastic jar, including the holes in the resolution plate, was filled with agar gel, which, for example, consists of distilled water, 1% agar powder, 2% Kappa carrageenan, and 22 μmol/kg of gadolinium contrast. The RF coil was placed inside the cavity of the phantom. In this example study, a portable vector network analyzer (VNA) was used to tune and match the RF coil after placing the RF coil inside the cavity of the phantom. The tune and match circuitry was connected to a pre-amplifier, and MRI scans were performed on the phantom.

In this example study, the tune and match of the flexible RF coil 102 (shown in FIG. 2) was performed by measuring the frequency response using the portable VNA for loaded and unloaded cases. Loaded S11 (reflection coefficient) was measured with the phantom placed under the RF coil while unloaded S11 was measured with no phantom present. In this example study, for both loaded and unloaded cases, the miniature flexible RF coil was tuned and matched to the resonance frequency of 123.2 MHz.

In this example study, the T1/T2 value of the agar phantom was measured to be 1250/64 ms, with T1/T2 map sequences. For example, standard resolution proton density Turbo Spin Echo (SD PD-TSE) sequences can be used to compare the flexible RF coil with a commercial 20-channel head coil, both quantitatively and qualitatively. In this example study, proton density was used because it is a direct measure of the maximum signal. For the example experiments to evaluate the RF coil apparatus, the two-dimensional (2D) SD PD-TSE sequence (e.g., echo time=9.1 ms; repetition time=3000 ms; refocusing angle=160°; bandwidth=250 Hz/pixel; acquisition matrix size=320×320×15; field of view=220×220×45 mm³; resolution=0.7×0.7×3 mm³; phase over sampling 0%; scan time 03:09 mm:ss; no parallel imaging) was scanned at 10 different coil rotation angles, ranging from 0° to 90°.

Given the expected higher SNR, in this example study the miniature flexible RF coil was also scanned with a 2D high-resolution proton density Turbo Spin Echo (HD PD-TSE) sequence at 0° and 60° coil angles. Images can be reconstructed from the frequency data directly via inverse Fast Fourier Transform (iFFT). In this example study, the HD PD-TSE scan (e.g., echo time=14 ms; repetition time=3000 ms; refocusing angle=160°; bandwidth=250 Hz/pixel; acquisition matrix size=320×320×35; field of view=64×64×25 mm³; resolution=0.2×0.2×0.7 mm³; phase over sampling 100%; scan time 06:21 mm:ss; no parallel imaging) was also performed on the commercial head coil using the same scan sequence. The commercial head coil images can be sum-of-square combined after coil reduction.

In this example study, for each angle, SNR measurements for the single-channel flexible RF coil were calculated from two repeated standard-resolution 2D PD-TSE scans. For this experiment, the region of interest (ROI) was divided into five cylindrical slices—each with 1 cm diameter and 3 mm thickness (e.g., as shown in FIGS. 3A and 3B)—inside the resolution plane center hole under the RF coil. When combined, the slices formed a 1 cm diameter region 3 mm to 18 mm away from the miniature coil. The defined ROI has a size comparable to a typical pituitary gland.

In this example study, SNR measurements were calculated with a known method for magnitude images of a single-coil array. SNR can be calculated as the ratio of signal and noise (SNR=S/σ). The signals can be measured as the mean intensity within the ROI, for Example, as given by:

$$S = \frac{1}{{N}_{ROI}} {\sum }_{i = 1}^{{N}_{ROI}} {A}_{{ROI}_{i}} \qquad Eqn . 4$$

where N is the number of samples and A is the pixel intensity. The noise can be measured as the background standard deviation on a signal-free region, for example, as given by:

$$σ = \sqrt{\frac{1}{{N}_{n}} {\sum }_{i = 1}^{{N}_{n}} {( {A}_{{n}_{i}} - \overline{{A}_{{n}_{1}}} )}^{2}} \qquad Eqn . 5$$

In this example experiment, the signal-free region was selected within the acrylic plastic part of the resolution block.

For the 20-channel commercial head coil, the SNR was calculated based on Kellman's method for root-sum-of-squares magnitude combining images, which is the gold standard for multi-channel phased array coils. The scaled noise covariance matrix was calculated from averaging pixel SNR within ROI from two repeated standard-resolution 2D PD-TSE scans. In this example study, standard resolution proton density Turbo Spin Echo (PD-TSE) MRI scans were performed on the phantom for SNR measurements for both the miniature flexible RF coil and the commercial head coil, and as mentioned above, a coil simulation model was developed to characterize the performance of the miniature flexible RF coil. For evaluation of the flexible RF coil and comparison with the conventional head coil, the SNR maps and the amplitudes of the simulated effective transverse Bi field distributions were plotted for θ from 0° to 90°, at defined ROIs from 4.5 mm to 16.5 mm distance to the coil (as shown in FIGS. 3A and 3B).

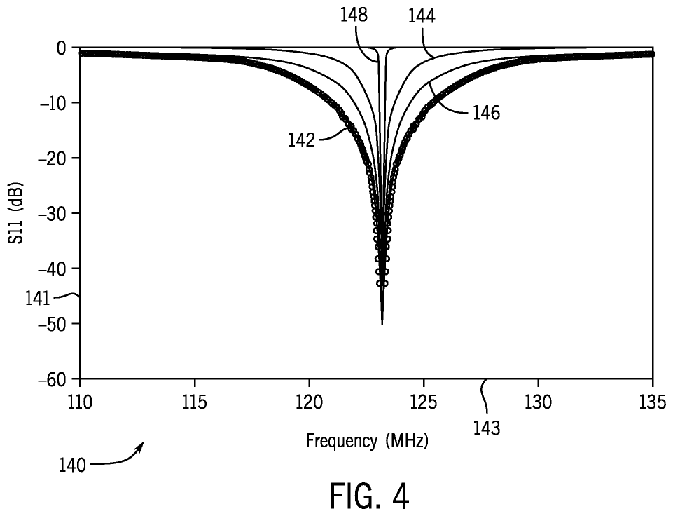

In this example study, S11 (the reflection coefficient) was recorded and then compared with the simulated S11 for the loaded and unloaded cases. FIG. 4 illustrates a comparison of a measured and simulated reflection coefficient, S11, of the flexible RF coil of the RF coil apparatus of FIG. 2 with and without a load in accordance with an embodiment. In this example study, the flexible RF coil in both loaded and unloaded cases was tuned and matched to the resonance frequency. For this experiment, the simulated S11 generally agreed with the measured S11. Graph 140 includes an S11 (dB) axis 141 and a frequency (MHz) 143 axis. Graph 140 shows a first S11 curve 142 for the measured S11 in the loaded condition, a second curve 144 for the measured S11 in the unloaded condition, a third curve 146 for the simulated S11 in the loaded condition, and a fourth curve 148 for the simulated S11 for the unloaded condition. The quality factor Q-factor can be approximated as the ratio of the resonant frequency (f₀) to the 3 dB bandwidth (Δf_{3dB}). In this example study, the simulated quality factors for the loaded case and the unloaded case were found to be Q_{loaded}^{sim}=16.88, Q_{unloaded}^{sim}=308, and the measured quality factors were found to be Q_{unloaded}^{mea}=11.18, Q_{unloaded}^{mea}=36.29. The lower Q-factors from the measurement are likely to be the result of the environment loss that was not included in the simulation. A common measure for sensitivity to loading is the ratio between the unloaded Q-factor and loaded Q-factor. In this example study, the measured Q-ratio as found to be Qᵣₐₜᵢₒ^{mea}=3.25 and the simulated Q-ratio is Aᵣₐₜᵢₒ^{sim}=18.25. A Q-ratio that is larger than 2 can indicate that the sample noise dominates the coil noise.

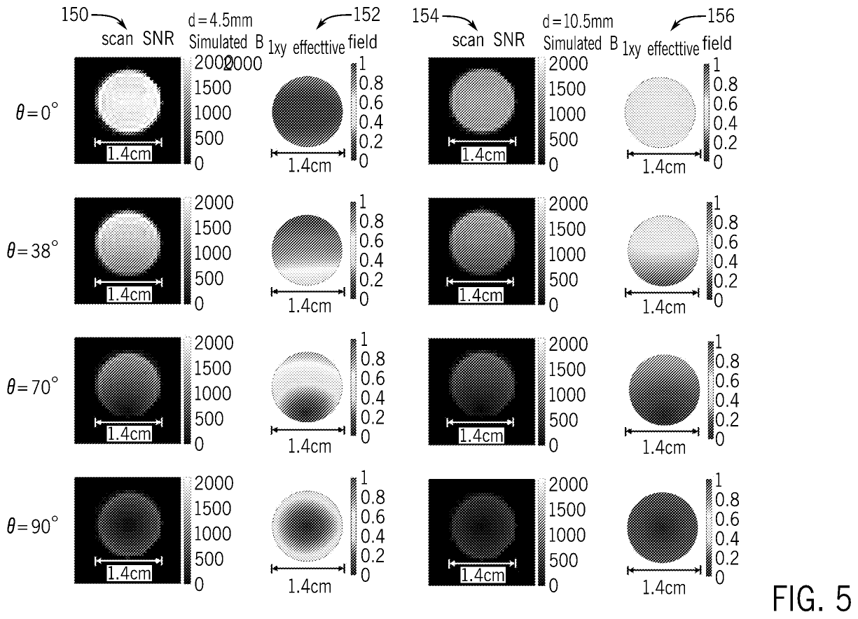

FIG. 5 illustrates example signal SNR maps and simulated effective transverse Bi field distributions at θ=0°, 38°, 70°, and 90° in accordance with an embodiment. FIG. 5 shows phantom scan signal in-plane SNR maps and the normalized amplitude of the simulated effective transverse Bi field distributions at θ=0°, 38°, 70°, and 90°, respectively, for two distances (or depths), d. In FIG. 5, d indicates the distance between the flexible RF coil (e.g., RF coil 102 shown in FIGS. 3A and 3B) and the imaging plane (e.g., imaging plane 132 shown in FIG. 3B). In this example study, the imaging planes were selected to be parallel to the coil plane, in particular, the imaging planes were selected parallel to the coil surface at d=4.5 mm and 10.5 mm below the coil, as a zoom-in shot on the resolution plane. The amplitudes of the simulated effective transverse Bi field distributions at the same coil depth distance and rotation angles as the SNR maps are also shown in FIG. 5. In the first column 150 and the third column 154 of FIG. 5, the SNR maps at the respective coil distance d and rotation angles θ are shown. In the second column 152 and the fourth column 156 of FIG. 5, the amplitudes of the simulated effective transverse Bi field distributions at the central hole on the resolution Linear color scale indicates the level of the SNR and the normalized B_{1xyeffective}. In this example study, the simulation fields were normalized based on the maximum B_{1xyeffective} field at d=4.5 mm.

As the coil angle increases, the overall SNR and the amplitude of the B_{1xyeffective} within the ROI can decrease. Because of the circular shape of the small flexible RF coil used in this example study, the magnetic field from the RF coil may not be uniform, and dead spots, where B_{1xyeffective} drops to zero, were observed in the in-plane results. When the rotation angles increased from 0° to 90°, the dead spot gradually moved from the edge of the ROI to the center of the ROI in both experiment and simulation. In this example study, the simulated field distribution qualitatively matched with the scan experiment SNR maps.

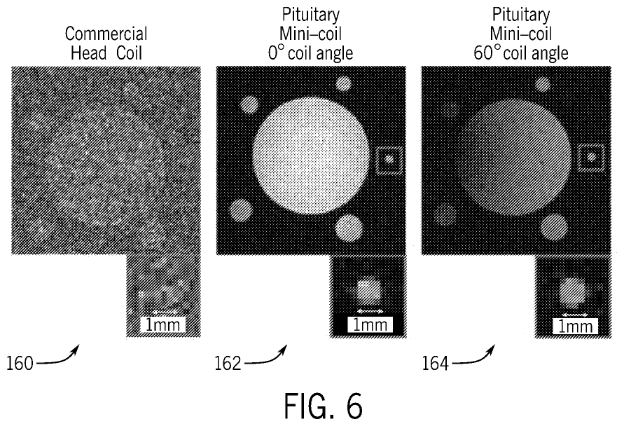

FIG. 6 illustrates a comparison of example high-resolution magnetic resonance (MR) images acquired using a commercial head coil and the flexible RF coil of the RF coil apparatus of FIG. 2 in accordance with an embodiment. The example images are high-resolution PD-TSE images of the pituitary. FIG. 6 compares a high-resolution PD-TSE image 160 acquired using a commercial head coil, a high resolution PD-TSE image 162 acquired using the miniature flexible RF coil at θ=0°, and a high resolution PD-TSE image 164 acquired using the miniature flexible RF coil at θ=60°. For this example, the voxel size is 0.2×0.2×0.7 mm³. In this example study, imaging planes were selected 1 cm from the RF coil. Images from flexible RF coil are at the same window level, while the image from the commercial head coil is at its own window level for better visualization Though the SNR decreases with increasing rotation angle, the phantom signal is still uniform at 600 coil angle, and the image SNR is high enough to clearly show the 1 mm hole on the resolution plate.

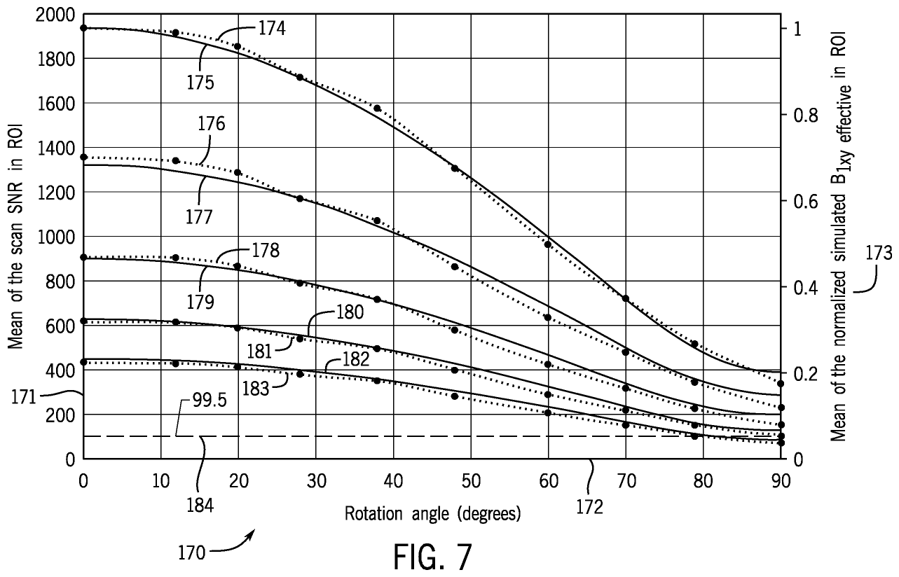

FIG. 7 is a graph illustrating mean SNR at various region of interest depths and rotation angles in accordance with an embodiment. Graph 170 shows the mean SNR (axis 171) of the ROI from the phantom scan with respect to distance from the RF coil (e.g., ROI depth) and the rotation angles (axis 172) and also provide a compared with the mean of the normalized effective transvers Bi field, B_{1xyeffective}, within the ROI (axis 173) from the simulation. Graph 170 includes a first mean SNR curve 174 for a distance d=4.5 mm for an acquired scan, a second mean SNR curve 175 for a distance d=4.5 mm for a simulated scan, a third mean SNR curve 176 for a distance d=7.5 mm for an acquired scan, a fourth mean SNR curve 177 for a distance d=7.5 mm for a simulated scan, a fifth mean SNR curve 178 for a distance d=10.5 mm for an acquired scan, a sixth mean SNR curve 179 for a distance d=10.5 mm for a simulated scan, a seventh mean SNR curve 180 for a distance d=13.5 mm for an acquired scan, an eighth mean SNR curve 181 for a distance d=13.5 mm for a simulated scan, a ninth mean SNR curve 182 for a distance d=16.5 mm for an acquired scan, a tenth mean SNR curve 183 for a distance d=16.5 mm for a simulated scan, and an eleventh mean SNR curve 184 for a conventional head coil.

In this example study, the effective transverse fields predicted by simulation fields were normalized at a single point, the mean B_{1xyeffective} at θ=0° at 4.5 mm below the coil. By setting this one point equal to the experimentally measured SNR in this example study, it can be seen that the simulations of magnetic field amplitude tracks with the experimentally measured SNR, with an error of 1.1% 0.8%. As shown in FIG. 7, the mean effective field at 0=900 dropped to around 20% of the mean-field found at θ=0° for all ROI depths. At θ=0°, the mean effective field at 16.5 mm slice was 23.1% of the mean effective field at 4.5 mm slice. For an ideal coil, at θ=90°, the coil magnetic field Bi is parallel to the main field B₀, and the SNR is expected to drop to zero. However, in the real case, only the B_{1y} component of the coil field may be parallel to B₀ at θ=90° (e.g., as shown in FIG. 3B), and spins can still be excited by B₁ₓ and B_{1z} components, providing a reduced but detectable signal. The mean SNR of the 20-channel commercial head coil based on Kellman's method was 99.5, which was uniform across the SNR.

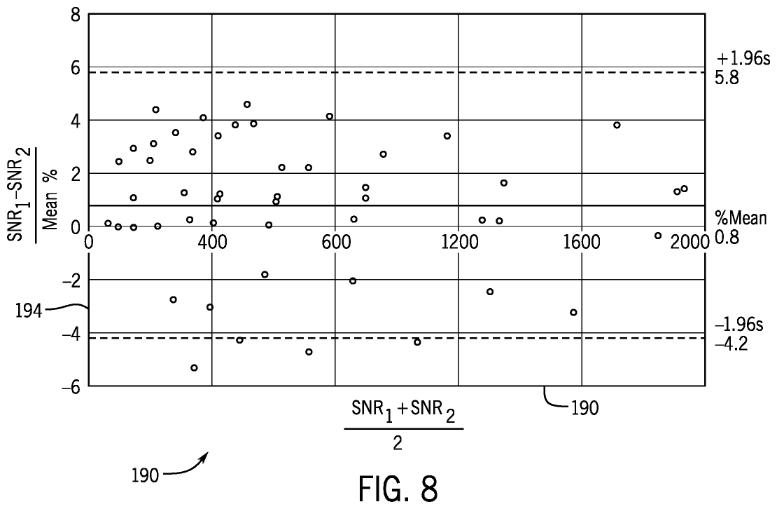

FIG. 8 shows a Bland-Altman plot for SNR of two repeated MR scans in accordance with an embodiment. In this example study, a Bland-Altman plot 190 of two repeated standard-resolution PD-TSE scans was generated to show the inter-scan SNR consistencies. In FIG. 9, that X-axis 192 is the mean of the two scans, and the Y-axis 194 is the percentage difference. The 95% confidence interval can indicate that the majority of repeated scans are within +5% difference, which demonstrated the consistency and the repeatability of measured SNRs from phantom scans.

In this example study, the SNR improvement using the miniature flexible RF coil compared to a commercial head coil was estimated using the simulated effective field at θ=30°. The SNR improvement factors of the disclosed flexible RF coil compared to the commercial head coil can be estimated based on the mean SNR from the scan of the miniature RF coil and the commercial head coil. In this example study, the MR imaging of the pituitary gland had a 12 to 19 times SNR improvement compared to the commercial head coil at the region close to the flexible RF coil, and at least 3 times of SNR improvement at the region further away from the RF coil. In an example “worst-case-scenario with an RF coil rotation angle of 60 degrees and a ROI depth of 16.5 mm, the flexible RF coil still produced a 2-fold relative increase in SNR.

The increased SNR from the miniature flexible RF coil enabled a markedly higher resolution MR imaging compared to the commercial head coil. In this example study, The voxel size of the high-resolution sequence was approximately 1/50th of the standard-resolution. Because the SNR is proportional to the voxel size, the flexible RF coil can enable a much-increased spatial resolution of that currently used with standard 3T imaging. At this reduced voxel size, the inadequate SNR associated with the commercial coil was demonstrable. The example phantom study suggests that pituitary adenomas of 1 mm and smaller may be detectable using the disclosed miniature intrasphenoidal flexible RF coil.

In this example, study, multiple aspects of the electromagnetic behavior and performance of the flexible RF coil were accurately simulated using a simulation model. In some embodiments, the simulation model may be implemented using known simulation software. The simulation of the effective magnetic field aligned with the experimentally measured SNR across a clinically relevant range of coil angles and distance, both in-plane pixel-wise and through-plane. The consistency of these two groups of simulation data and experiment data validates both the numerical simulation model and SNR experiments. The SNR from repeated scans also had little difference demonstrating precise SNR measurements.

In the example study, the coil simulation model was validated with the phantom scan experiment, and the coil simulation model can be important in studying the interaction between the RF fields from the surface coil and the ROI or the phantom. As demonstrated in the example study, the simulated coil field can potentially be used to predict the SNR improvement of using the miniature flexible RF coil compared to a commercial RF coil (e.g., a commercial head coil). It can also allow the simulation of the performance of other RF coil designs with different diameters, geometries, resonance frequencies, and placement configurations, and therefore accelerate the development of improved RF coil designs. Furthermore, the simulation model can enable selection of an optimal flexible RF coil size and shape from a set of existing flexible RF coil designs based on the specific anatomy (e.g., the specific physical spatial constraints of the anatomy) of each subject.

FIG. 9 shows an example of an MRI system 200 that may be used with the RF coil apparatus and methods described herein. MRI system 200 includes an operator workstation 202, which may include a display 204, one or more input devices 206 (e.g., a keyboard, a mouse), and a processor 208. The processor 208 may include a commercially available programmable machine running a commercially available operating system. The operator workstation 202 provides an operator interface that facilitates entering scan parameters into the MRI system 200. The operator workstation 202 may be coupled to different servers, including, for example, a pulse sequence server 210, a data acquisition server 212, a data processing server 214, and a data store server 216. The operator workstation 202 and the servers 210, 212, 214, and 216 may be connected via a communication system 240, which may include wired or wireless network connections.

The pulse sequence server 210 functions in response to instructions provided by the operator workstation 202 to operate a gradient system 218 and a radiofrequency (“RF”) system 220. Gradient waveforms for performing a prescribed scan are produced and applied to the gradient system 218, which then excites gradient coils in an assembly 222 to produce the magnetic field gradients Gₓ, G_{y}, and G_{z} that are used for spatially encoding magnetic resonance signals. The gradient coil assembly 222 forms part of a magnet assembly 224 that includes a polarizing magnet 226 and a whole-body RF coil 228. A subject 250 (e.g., a patient) may be positioned in the magnet assembly 224 on a patient table (or scanner table) 252.

RF waveforms are applied by the RF system 220 to the RF coil 228, or a separate local coil to perform the prescribed magnetic resonance pulse sequence. Responsive magnetic resonance signals detected by the RF coil 228, or a separate local coil (e.g., the flexible RF coil 202 shown in FIGS. 1 and 2, are received by the RF system 220. The responsive magnetic resonance signals may be amplified, demodulated, filtered, and digitized under direction of commands produced by the pulse sequence server 210. The RF system 220 includes an RF transmitter for producing a wide variety of RF pulses used in MRI pulse sequences. The RF transmitter is responsive to the prescribed scan and direction from the pulse sequence server 210 to produce RF pulses of the desired frequency, phase, and pulse amplitude waveform. The generated RF pulses may be applied to the whole-body RF coil 228 or to one or more local coils (e.g., flexible RF coil 202 shown in FIGS. 1 and 2) or coil arrays.

The RF system 220 also includes one or more RF receiver channels. An RF receiver channel includes an RF preamplifier that amplifies the magnetic resonance signal received by the coil 228 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} \qquad Eqn .. 6$$

and the phase of the received magnetic resonance signal may also be determined according to the following relationship:

$$φ = {tan}^{1} ( \frac{Q}{I} ) \qquad Eqn . 7$$

The pulse sequence server 210 may receive patient data from a physiological acquisition controller 230. By way of example, the physiological acquisition controller 230 may receive signals from a number of different sensors connected to the patient, including electrocardiograph (“ECG”) signals from electrodes, or respiratory signals from a respiratory bellows or other respiratory monitoring devices. These signals may be used by the pulse sequence server 210 to synchronize, or “gate,” the performance of the scan with the subject's heart beat or respiration.

The pulse sequence server 210 may also connect to a scan room interface circuit 232 that receives signals from various sensors associated with the condition of the patient and the magnet system. Through the scan room interface circuit 232, a patient positioning system 234 can receive commands to move the patient to desired positions during the scan.

The digitized magnetic resonance signal samples produced by the RF system 220 are received by the data acquisition server 212. The data acquisition server 212 operates in response to instructions downloaded from the operator workstation 202 to receive the real-time magnetic resonance data and provide buffer storage, so that data is not lost by data overrun. In some scans, the data acquisition server 212 passes the acquired magnetic resonance data to the data processor server 214. In scans that require information derived from acquired magnetic resonance data to control the further performance of the scan, the data acquisition server 212 may be programmed to produce such information and convey it to the pulse sequence server 210. For example, during pre-scans, magnetic resonance data may be acquired and used to calibrate the pulse sequence performed by the pulse sequence server 210. As another example, navigator signals may be acquired and used to adjust the operating parameters of the RF system 220 or the gradient system 218, or to control the view order in which k-space is sampled. In still another example, the data acquisition server 212 may also process magnetic resonance signals used to detect the arrival of a contrast agent in a magnetic resonance angiography (“MRA”) scan. For example, the data acquisition server 212 may acquire magnetic resonance data and processes it in real-time to produce information that is used to control the scan.

The digitized magnetic resonance signal samples produced by the RF system 220 are received by the data acquisition server 212. The data acquisition server 212 operates in response to instructions downloaded from the operator workstation 202 to receive the real-time magnetic resonance data and provide buffer storage, so that data is not lost by data overrun. In some scans, the data acquisition server 212 passes the acquired magnetic resonance data to the data processor server 214. In scans that require information derived from acquired magnetic resonance data to control the further performance of the scan, the data acquisition server 212 may be programmed to produce such information and convey it to the pulse sequence server 210. For example, during pre-scans, magnetic resonance data may be acquired and used to calibrate the pulse sequence performed by the pulse sequence server 210. As another example, navigator signals may be acquired and used to adjust the operating parameters of the RF system 220 or the gradient system 218, or to control the view order in which k-space is sampled. In still another example, the data acquisition server 212 may also process magnetic resonance signals used to detect the arrival of a contrast agent in a magnetic resonance angiography (“MRA”) scan. For example, the data acquisition server 212 may acquire magnetic resonance data and processes it in real-time to produce information that is used to control the scan.

Images reconstructed by the data processing server 214 are conveyed back to the operator workstation 202 for storage. Real-time images may be stored in a data base memory cache, from which they may be output to operator display 204 or a display 236. Batch mode images or selected real time images may be stored in a host database on disc storage 238. When such images have been reconstructed and transferred to storage, the data processing server 214 may notify the data store server 216 on the operator workstation 202. The operator workstation 202 may be used by an operator to archive the images, produce films, or send the images via a network to other facilities.

The MRI system 200 may also include one or more networked workstations 242. For example, a networked workstation 242 may include a display 244, one or more input devices 246 (e.g., a keyboard, a mouse), and a processor 248. The networked workstation 242 may be located within the same facility as the operator workstation 202, or in a different facility, such as a different healthcare institution or clinic.

The networked workstation 242 may gain remote access to the data processing server 214 or data store server 216 via the communication system 240. Accordingly, multiple networked workstations 242 may have access to the data processing server 214 and the data store server 216. In this manner, magnetic resonance data, reconstructed images, or other data may be exchanged between the data processing server 214 or the data store server 216 and the networked workstations 242, such that the data or images may be remotely processed by a networked workstation 242.

The present invention has been described in terms of one or more preferred embodiments, and it should be appreciated that many equivalents, alternatives, variations, and modifications, aside from those expressly stated, are possible and within the scope of the invention.

1. An RF coil apparatus for magnetic resonance imaging (MRI), the RF coil apparatus comprising:
a flexible RF coil configured to be positioned in a cavity of a subject proximate to a region of interest located internally in the subject;
a circuit assembly coupled to the flexible RF coil and configured to be positioned external to the subject, the circuit assembly comprising adjustable tune and match components;
a first connector connected between the flexible RF coil and the circuit assembly; and
a second connector coupled to the circuit assembly and configured to be coupled to an MRI system.

2. The RF coil apparatus according to claim 1, wherein the flexible RF coil is a single loop coil.

3. The RF coil apparatus according to claim 1, wherein the flexible RF coil is a butterfly coil.

4. The RF coil apparatus according to claim 1, wherein the flexible RF coil is a figure-of-eight coil.

5. The RF coil apparatus according to claim 1, wherein the flexible RF coil is an array of coils.

6. The RF coil apparatus acceding to claim 1, wherein the first connector is a cable.

7. The RF coil apparatus according to claim 1, wherein the circuit assembly further comprises a preamplifier.

8. The RF coil assembly according to claim 1, wherein the region of interest is a pituitary gland and the cavity includes a sphenoidal sinus cavity.

9. The RF coil apparatus according to claim 1, wherein the adjustable tune and match components are configured to tune a resonance frequency of the RF coil.

10. A magnetic resonance imaging (MRI) system comprising:
a magnet system configured to generate a polarizing magnetic field about at least a portion of a subject;
a magnetic gradient system including a plurality of magnetic gradient coils configured to apply at least one magnetic gradient field to the polarizing magnetic field; and
a radio frequency (RF) system configured to apply an RF field to the subject and to receive magnetic resonance signals from the subject, wherein RF system includes an RF coil apparatus comprising:
a flexible RF coil configured to be positioned in a cavity of a subject proximate to a region of interest located internally in the subject;
a circuit assembly coupled to the flexible RF coil and configured to be positioned external to the subject, the circuit assembly comprising adjustable tune and match components;
a first connector connected between the flexible RF coil and the circuit assembly; and
a second connector coupled to the circuit assembly and the RF system.

11. The MRI system according to claim 10, wherein the flexible RF coil is a single loop coil.

12. The MRI system according to claim 10, wherein the flexible RF coil is a butterfly coil.

13. The MRI system according to claim 10, wherein the flexible RF coil is a figure-of-eight coil.

14. The MRI system according to claim 10, wherein the flexible RF coil is an array of coils.

15. The MRI system according to claim 10, wherein the circuit assembly further comprises a preamplifier.

16. The MRI system according to claim 10, wherein the adjustable tune and match components are configured to tune a resonance frequency of the RF coil.

17. The MRI system according to claim 10, wherein the region of interest is a pituitary gland and the cavity includes a sphenoidal sinus cavity.
